(19) United States
(12) Patent Application Publication
(10) Pub. No.: US 2019/0375138 A1
(43) Pub. Date: Dec. 12, 2019

(54) METHOD OF CONVERTING COMPOSITE SHEET TO FLEXIBLE KEYPAD AND FLEXIBLE KEYPAD

(71) Applicant: INDUSTRY-ACADEMIA COOPERATION GROUP OF SEJONG UNIVERSITY, Seoul (KR)

(72) Inventor: Kee-sun SOHN, Seoul (KR)

(21) Appl. No.: 16/427,529

(22) Filed: May 31, 2019

(30) Foreign Application Priority Data
Jun. 8, 2018 (KR) 10-2018-0065753

(51) Int. Cl. B29C 43/58; B29C 43/00; B29C 43/02; H03K 17/96; G06F 3/045; G06N 3/08

(52) U.S. Cl. CPC B29C 43/58; B29C 43/003; B29C 43/02; B29K 2105/167; G06F 3/045; G06N 3/08; H03K 17/9647

(57) ABSTRACT

The present invention relates to a method of converting a composite sheet into a multifunctional flexible keypad. The method according to the invention includes preparing a composite sheet including a flexible sheet and conductive particles dispersed therein, detecting and collecting position information on an applied pressure and a change in electrical resistance of the composite sheet from a plurality of probe terminals provided on the sheet while applying a pressure a plurality of times to an arbitrary position of the composite sheet, performing machine learning using the collected position information and electrical resistance information, and estimating position information on a pressure applied by a user to the composite sheet by using a Deep Neural Network (DNN) model derived through the machine learning when the user applies the pressure to a predetermined position of the composite sheet.

### BACKGROUND OF THE INVENTION

### 1. Field of the Invention

The present invention relates to a method of converting a simple composite sheet including a flexible material and conductive particles into a flexible keypad that is excellent in flexibility and portability by using a machine learning technique, and a flexible keypad manufactured by the method.

### 2. Description of the Related Art

A portable information processing device such as a cellular phone or a PDA has many inconveniences in inputting information, and thus there is an increasing demand for a keypad having excellent portability and facilitating input of information.

As to flexible and portable keypads, as disclosed in the following patent documents, a flexible keypad is known which has a hard push button and a tactile sensor array pattern embedded in a sheet made of a flexible material and may thus be folded or rolled into a roll.

The tactile sensor array pattern may be configured using various physical elements such as resistive, capacitive, inductive, piezoresistive, optical, magnetic, piezoelectric, and hydraulic elements. However, since all tactile sensor array patterns using any type above include fragile components, the flexibility that may be achieved by conventional flexible keypads has a limited degree of bendability or rollability.

However, when used freely in everyday life, flexible keypads may be folded into various forms or roughly wrinkled. In this case, the conventional flexible keypad may be broken, resulting in a problem that conventional flexible keypads cannot have such a flexibility enough to be freely used in everyday life.

### PRIOR ART DOCUMENT)

### Patent Literature

(Patent Document 1) Korean Patent Laid-Open Publication No. 2013-0060022

(Patent Document 2) Korean Patent Laid-Open Publication No. 2009-0029411

### SUMMARY OF THE INVENTION

The present invention provides a method of converting a sheet, which is made of a simple composite material and does not have a specific pattern, into a flexible keypad capable of ensuring high accuracy while remarkably improving flexibility as compared with conventional flexible keypads, and also provides a flexible keypad manufactured by this method.

According to an embodiment of the invention, there is provided a method of converting a composite sheet into a multifunctional flexible keypad, the method including: preparing a composite sheet including a flexible sheet and conductive particles dispersed therein; detecting and collecting position information of an applied pressure and a change in electrical resistance of the composite sheet from a plurality of probe terminals provided on the sheet while applying a pressure a plurality of times to an arbitrary position of the composite sheet; performing machine learning using the collected position information and electrical resistance information; and estimating position information on a pressure applied by a user to the composite sheet using a Deep Neural Network (DNN) model derived through the machine learning when the user applies the pressure to a predetermined position of the composite sheet.

According to another embodiment of the invention, provided are a flexible sheet in which conductive particles are dispersed, and a plurality of probe terminals configured to detect a change in electrical resistance caused by a pressure applied to the flexible sheet from a plurality of positions of the flexible sheet.

### BRIEF DESCRIPTION OF THE DRAWINGS

FIG. 1 is a schematic view of a process for manufacturing a composite sheet used in an embodiment of the invention;

FIG. 2A shows a training dataset structure for all key positions of a keypad in an embodiment of the invention;

FIG. 2B shows a test dataset structure for all key positions of a keypad in an embodiment of the invention;

FIG. 2C shows a DNN architecture for pressure regression in an embodiment of the invention;

FIG. 2D shows experimental data and data predicted by a pressure regression DNN model;

FIG. 3A shows training set accuracy for pressure region I;

FIG. 3B shows test set accuracy for pressure region I;

FIG. 3C shows training set accuracy for pressure region II;

FIG. 3D shows test accuracy for pressure region II; and

FIG. 4 shows a data collection state which is same as before, when machine learning is performed on a composite sheet according to an embodiment of the invention, then a user severely wrinkles the composite sheet, and the wrinkled composite sheet is recovered.

### DETAILED DESCRIPTION OF THE EXEMPLARY EMBODIMENTS

Hereinafter, embodiments of the invention will be described with reference to the accompanying drawings. In describing the invention below, detailed descriptions of well-known configurations or functions will be omitted if it is determined that they would obscure the subject matter of the invention. Furthermore, when it is described that one comprises (or includes or has) some elements, it should be understood that it may comprise (or include or has) only those elements, or it may comprise (or include or have) other elements as well as those elements if there is no specific limitation.

A method according to the invention includes preparing a composite sheet including a flexible sheet and conductive particles dispersed therein, detecting and collecting, from a plurality of probe terminals provided on the sheet, position information on a pressure applied to an arbitrary position of the composite sheet and a change in electrical resistance of the composite sheet while applying a pressure to the composite sheet a plurality of times, performing machine learning using the collected position information and electrical resistance information, and estimating position information on a pressure applied to the composite sheet by a user, by using a Deep Neural Network (DNN) model derived through the machine learning when the user applies the pressure to a predetermined position of the composite sheet.

Any flexible sheet may be used without limitation as long as the sheet is flexible enough to generate piezo-resistance on the conductive particles existing therein due to external pressure. Preferably, the flexible sheet may be made of a soft polymer material and may be one selected from, for example, polydimethylsiloxane (PDMS), polymethylmethacrylate (PMMA), epoxy resin, urethane resin or silicone rubber, but the invention is not limited thereto.

The conductive particles may include at least one of various shapes such as a particulate shape, a fiber shape, a flake shape, and a plate shape.

The conductive particles are substances that generate a change in electrical resistance when a pressure is applied thereto. The amount of the conductive particles to be used is not limited as long as the amount allows the change in electrical resistance to be detected from the probe terminal when the pressure is applied. For example, a material such as carbon nanotube (CNT) may be used.

The collecting of the position information and the electrical resistance may include dividing the composite sheet into predetermined virtual areas, and detecting a pressure-applied virtual area and the electrical resistance of the composite sheet at the time of pressure application through a plurality of ports disposed at the edges of the composite sheet.

In addition, it is possible to perform machine learning by further collecting pressure intensity information in addition to the position information on the applied pressure. In this case, when a user presses a predetermined position of the composite sheet, a Deep Neural Network (DNN) model derived through the machine learning is used to derive the pressure intensity information together with the position on the pressure applied by the user. For example, it is possible to generate more various input information in the same seat area, for example, to replace ‘shift key’ or ‘case conversion’ with ‘pressure intensity’.

The flexible keypad according to the invention is provided with a flexible sheet in which conductive particles are dispersed and a plurality of probe terminals for detecting an electric resistance signal generated by a pressure applied to the flexible sheet from a plurality of positions of the flexible sheet.

In the keypad, at least one among letters, numbers and symbols of the keypad may be printed on one side of the flexible sheet.

### Embodiment

Manufacturing of Composite Sheet

In the embodiment of the invention, a super-soft composite sheet was prepared with a homogeneous mixture of carbon nanotube (CNT) (Carbon Nano-material Technology Co., Ltd.) and silicone rubber (Ecoflex™, platinum-catalyzed silicone).

The double CNT having a multi-wall with a length of 5 μm and a diameter of 20 nm was used. Also, silicone rubber, which is used as a soft polymer material forming the matrix, is more desirable than other soft polymer materials such as PMMA, PDMS, epoxy resin and urethane because detection is easy in a range of detecting a general tactile pressure ranging from 0 to 50 kPa.

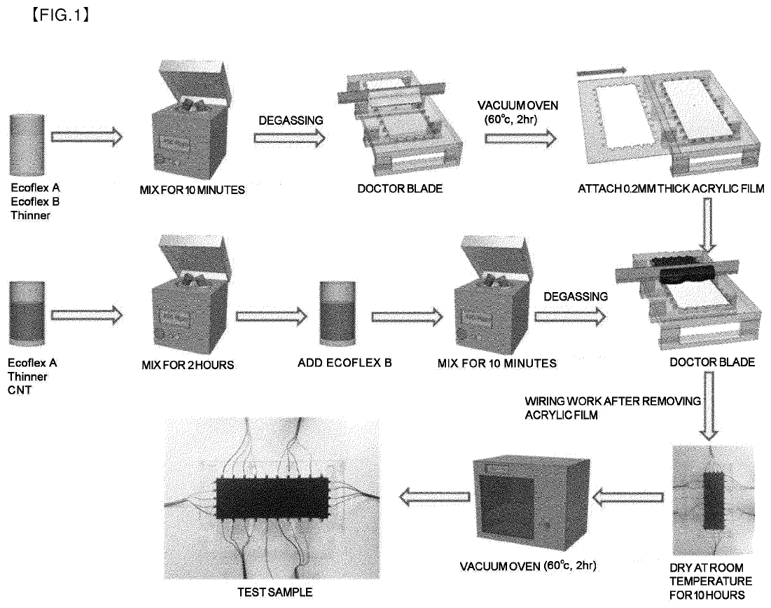

FIG. 1 is a schematic view of a process for manufacturing a composite sheet used in an embodiment of the invention.

Ecoflex used in the embodiment of the invention is composed of two components, and the mixing ratio of Ecoflex A and Ecoflex B is 1:1. In addition, a thinner to reduce viscosity (Thinning Ecoflex™ Silicones) was also added to promote dispersion of the CNTs and to provide softness to the sheet.

CNT was mixed with Ecoflex A to give 1 wt % of the total weight of the matrix (Ecoflex A+Ecoflex B+thinner). In addition, in order to uniformly disperse the CNTs in the Ecoflex without aggregation, several alumina polishing balls having a diameter of 10 mm were charged, and mixing was then performed in a planetary shear mixer at a speed of 400 rpm for 2 hours.

Then, the same amount of Ecoflex B as that of Ecoflex A was added, mixing was performed again using the planetary shear mixer for 10 minutes, the resultant mixture was left in a vacuum state for 10 minutes to remove bubbles trapped in nanocomposites.

A mold for manufacturing the composite sheet was provided such that sheets of two dimensions of 160×59×0.2 mm and 80×59×0.2 mm in width, length, and thickness may be cast. Furthermore, the mold has several extensions on each side surface to have a dimension of 5×3×5 mm, in order to facilitate wiring for the probe terminal to detect electrical resistance.

Using the doctor blade technique, the mixed nanocomposite was injected into the mold and cast to form the wiring. The wired composite sheet was left at room temperature for 10 hours for solidification, and finally heated in a vacuum oven at 60° C. for 2 hours to be fully solidified.

The composite sheet manufactured in such a manner shows a change in electrical resistance due to the applied load. In addition, the resistance of the MWCNT-Ecoflex material is independent of the strain rate, and this means that the piezo-resistance depends on the instantaneous state of the conductive CNT distribution in the insulating Ecoflex matrix, but not on the strain rate.

Machine Learning for Keypad Conversion

(1) Virtual Keyset and Probe Terminal

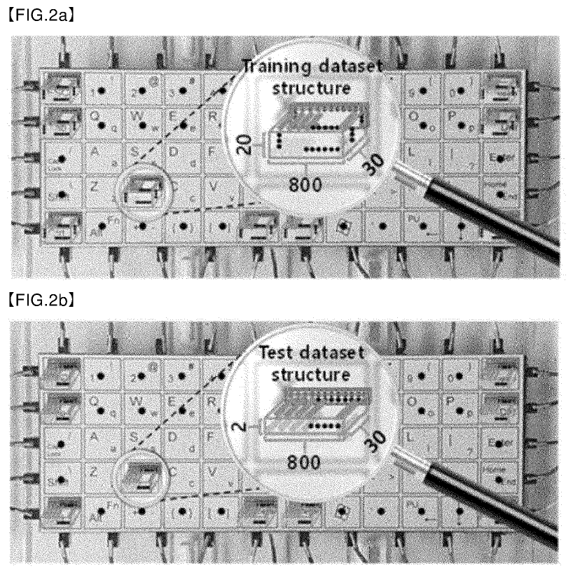

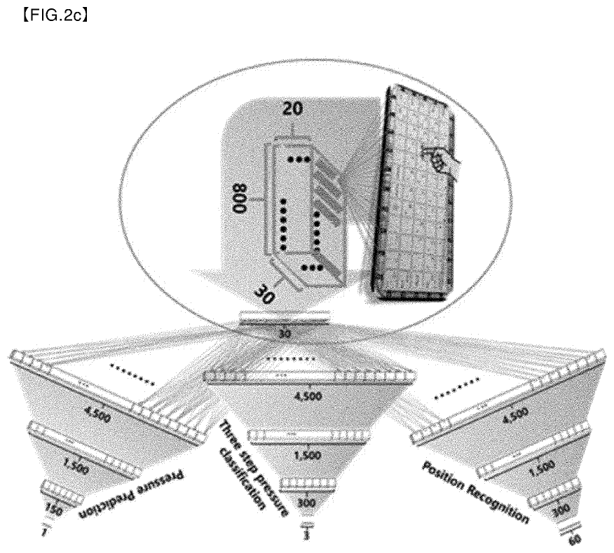

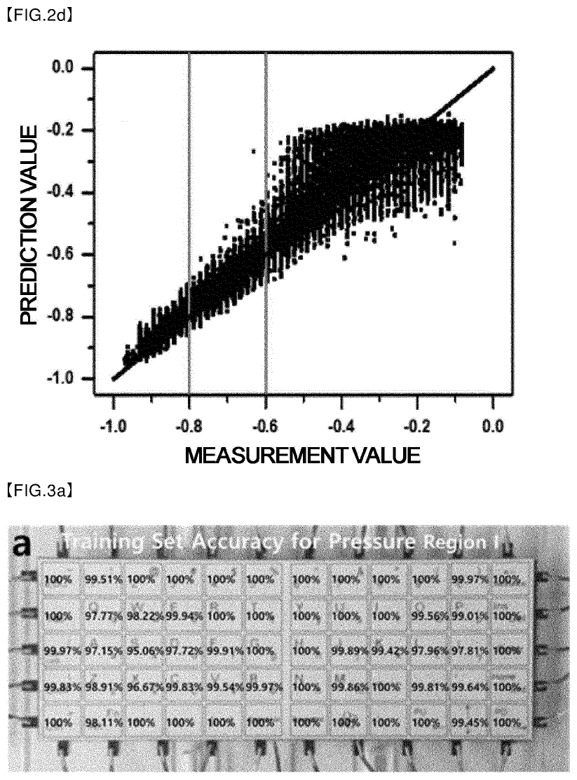

FIGS. 2A and 2B show a key array for converting a composite sheet into a keypad and an electrode array serving as a probe terminal according to an embodiment of the invention.

In an embodiment of the invention, a keyset of 60 virtual keys are formed on the surface of the composite sheet and 30 probe terminals were disposed along the edges of the composite sheet. The virtual keyset is designed to have virtual area sections although there is no physical device to distinguish each key button.

Minimizing the number of the probe terminals may simplify the structure of the keypad and is thus preferable. If the number of probe terminals is too small, the performance of the DNN model by machine learning deteriorates, so that it is preferable to set the number of the probe terminals to be equal to or larger than the number that may ensure the minimum accuracy with which the keypad may be operated.

(2) Data Structure for Learning and Test

The dataset structure for all the key positions of the keypad is composed of the training dataset shown in FIG. 2A and the test dataset shown in FIG. 2B.

The dataset for each key is indicated by a box. The green boxes represent a set of electrical resistance data as input data, and a red slab represents a set of pressure data as a label.

In the dataset, the width 800 represents the electrical resistance data collected sequentially from the probe terminal for 0.16 seconds, and this means that the touch (or pressure) applied to a particular key for 0.16 seconds will produce 800 sequential electrical resistances per probe terminal. Also, the depth 30 represents the number of probe terminals from which the electrical resistance signal is collected, and the height (20 in the case of the training dataset and 2 in the case of the test dataset) represents the number of touches per key position.

The input feature is vectorized into a 30-dimensional vector (a blue bar in a green box), and the component represents the actual number of resistances measured at each of the 30 probe terminals. At this time, a certain level of pressure (0 to 6.7 kPa) is applied to the specific key position for 0.16 seconds.

Through this, 800 30-dimensional input vectors are collected along with 800 pressure values per key position, and 20 independent measurements are performed at each key position, so that the total training dataset for 60 keys constitutes 960,000 (800×60×20) 30-dimensional input vectors.

The label (output) data is an alphabetic, numeric and function key relating to the associated key position, and the label data for the displacement (pressure) is the real number indicated by the red slab.

On the other hand, as shown in FIG. 2B, the structure of the tester dataset is smaller than the training dataset, but has a similar structure.

(3) Deep Neural Network (DNN) Architecture for Pressure Recognition

Since a static bias (10V) is applied to all probe terminals in parallel and the center of the keypad is grounded, touching a specific position of the keypad causes a change in electrical resistance in some probe terminals, and at this time, most of the probe terminals far from the touch position do not change significantly. Regardless of the touch position, the change in the electrical resistance signal has a consistent relationship with the applied pressure. In an embodiment of the invention, when touched at different positions, all electrical resistance data collected from all probe terminals were collected and used as input values.

The DNN model for pressure recognition used in the embodiment of the invention operated properly at all touch positions. This means that the exact pressure of the touch is recognized in real time regardless of which key position is in touch.

FIG. 2C shows a DNN architecture according to an embodiment of the invention. FIG. 2D shows experimental data and data predicted by the pressure regression DNN model.

The architecture shown in green in FIG. 2C is a pressure prediction architecture, and there are 30-4500-1500-150-1 nodes belonging to each layer from the input layer to the output layer.

In this architecture, a Rectified Linear Unit (ReLU) adopting an activation function is applied up to the third layer so as to have a max (0, x) threshold, and 30% dropout is applied, so that an operation is performed. The activation function of the last connected layer adopts the linear activation function.

In the pressure prediction architecture, electrical resistance signal data collected from 30 probe terminals is monitored and learning is performed by performing regression on the actual value for pressure. This learning process may calculate overly precise results compared to the pressure information required for actual keypad operation, thereby complicating the learning process.

However, for proper keypad operation, a much simpler learning process may be enough. This is because an accurate pressure value at the time of touching the keypad is not necessarily required for actual keypad operation.

For this, in the embodiment of the invention, the pressure is classified into three categories. For example, the pressure is classified into a low-level touch pressure to distinguish the touch unrelated to the user's intention, a middle-level touch (normal touch) pressure that defines the important function of the keypad, and a high-level strong touch pressure that defines special functions such as the ‘Shift’ command or the ‘Case Conversion’ command.

In the case of the strong touch, for example, if a key is pressurized above a certain threshold value, it is recognized as an upper case, and otherwise, it may be recognized as a lowercase letter. This may remove the ‘Shift’ key from the DNN-based keypad.

The architecture shown in blue in FIG. 2C is for implementing a three-step pressure classification in which the pressure is divided into three steps as described above.

This architecture has the same structure except for the last two layers when compared to the architecture for pressure prediction.

In a three-step pressure classification architecture, there are 30-4500-1500-300-3 nodes belonging to each layer from the input layer to the output layer. Although a simple linear activation function was applied from the input layer to the third layer, the activation function of the last connected layer adopts the softmax function.

In the previous three layers, a Rectified Linear Unit (ReLU) in which an activation function is used to have a max(0, x) threshold is applied and 30% dropout is applied so that an operation is performed. In the pressure regression method, it provides an immediate actual value for the pressure at the time of touch, but the three-stage pressure classification method uses a simple classification architecture.

Table 1 below shows the mean square root error (% RMSE) and mean absolute error (MAE) for the pressure regression.

TABLE 1

| | | All ranges | Area O | Area I | Area II |
|---|---|---|---|---|---|
| Test | % RMSE | 11.246 | 22.3562 | 4.0898 | 3.0758 |
| | MAE | 0.0418 | 0.0558 | 0.0230 | 0.0219 |
| Training | % RMSE | 10.1265 | 20.2280 | 3.7217 | 2.4612 |
| | MAE | 0.0368 | 0.0506 | 0.0197 | 0.0166 |

As seen in Table 1, the accuracy of the full range pressure regression value was acceptable in terms of mean square error and MAE.

As seen in FIG. 2D, in the touch operation initial step, there is considerable noise in the low-pressure area, but noise is immediately reduced after passing through this low-pressure area (area 0). Actually, if the data contains a lot of noise, the values of RMSE and MAE are low.

Since area I and area II are important from a practical point of view, these two areas are important to determine whether touch is soft or strong. However, as seen in Table 1, fittings in these two areas show high accuracy with few errors.

On the other hand, although the fitting accuracy of the entire area including the area with the high initial noise (area O) and the area with low noise (area I, area II) is low, data including noise is not used for actual keypad operation, and thus the reduction in overall fitting accuracy due to initial noise is not a problem.

As described above, step classification was more practical than regression of actual pressure values, and through this, it can be understood that implementation of the keypad function is possible.

On the other hand, the DNN architecture of the three-step classification model operated very well, and in relation to the performance, test and training accuracy values were 94.95% and 96.21%, respectively. The accuracy was obtained based on the individual data points. When applying a group data specific classification method that selects the most frequently occurring labels in a data group collected for a certain period of time, for example, a few milliseconds, as a correct answer, 100% accuracy is guaranteed, and this type of group data-based classification system is applied to the actual keypad system.

(4) DNN Architecture for Key Recognition

What should be done simultaneously with step pressure recognition is to recognize the key that is touched.

As shown in FIG. 2A, the embodiment of the invention employs an array of 60 key. The key position recognition DNN architecture in FIG. 2C is configured to allow 60 label classifications.

The DNN structure is similar to the pressure prediction model and the three-step pressure classification model except for the last two layers.

There are 30-4500-1500-300-60 nodes belonging to each layer from the input layer to the output layer. Although the ReLu activation function was applied from the input layer to the third layer, the activation function of the last connected layer adopts the softmax function.

A Rectified Linear Unit (ReLU) in which the activation function is used to have a max(0,x) threshold for the previous three hidden layers was adopted and a 30%-dropout was introduced.

As a result, individual data-based and group data-based position recognition showed excellent accuracy for both test datasets and training datasets.

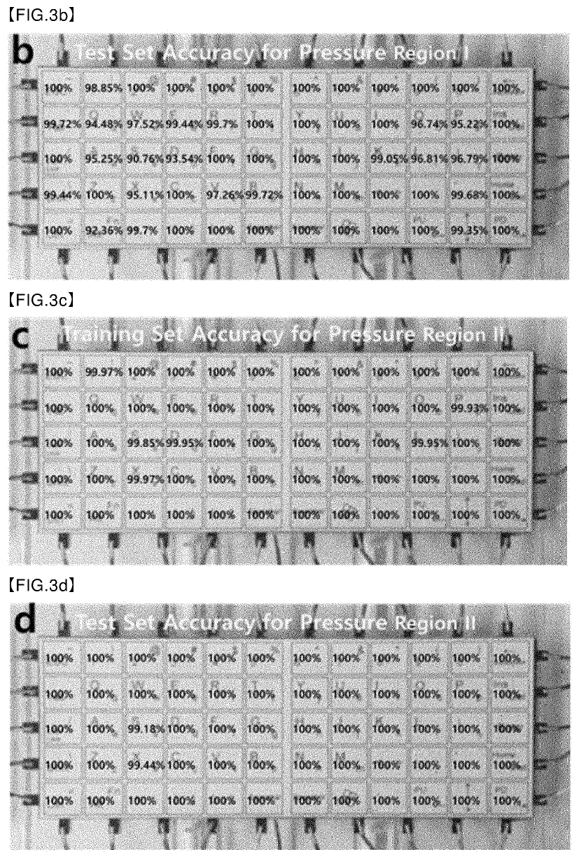

The individual data-based position recognition provides real-time accuracy that is 100% or close to 100%, as seen in FIGS. 3A to 3D. The overall accuracy of the strong touch (area II) showed more accurate results than that of the weak touch (area I). The test accuracy is slightly lower than the training accuracy, but is similar to a level of the general trend of many machine learning.

Overall, the training and testing accuracies for individual data-based recognition of strong touches and weak touches for 60 keys are about 100%. However, the test accuracy of the letters for weak touches dropped to 90.76%.

However, if group data-based position recognition is used instead of individual data-based position recognition even in the current step, 100% accuracy is possible for all positions in every situation.

It is regarded that, in group-based data-based position recognition, independent touch operation occurs for 0.16 seconds as a data unit (so-called group data). That is, a position having the highest frequency among the data within a certain time is recognized as a test result. The time required for reliable group data-based position recognition may be reduced to several milliseconds, and this is no problem even when the world's fastest typists enter the keypad.

When using a group-based data-based position recognition system, there was no case where the touch could not identify the key under any circumstances. That is, since the group data-based position recognition system meets the substantial requirements for the actual keypad function, this may be practical when a DNN-based keypad is sold as a commercially available application.

(5) Flexibility Test

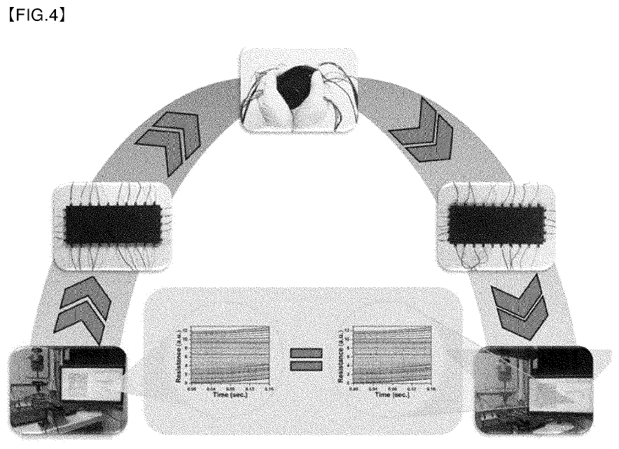

In order to evaluate the flexibility of the composite sheet converted into the keypad according to the embodiment of the invention, as shown in FIG. 4, after the composite sheet was severely wrinkled and then unwrinkled, it was evaluated whether the sheet could be used as a keypad without re-training process.

As a result, as shown in FIG. 4, even after the severe wrinkling, the electrical resistance signals detected by 30 probe terminals did not change, and the same DNN model could be used. That is, the keypad according to the embodiment of the invention may be used as a keypad without re-training even after severe deformation.

According to the invention, through a machine learning technique, a simple composite sheet containing randomly dispersed conductive particles in a flexible sheet without a pattern is converted into a smart flexible keypad that, when a user touches the sheet, may recognize a touch intensity as well as a touch position.

As such, when a simple large-area composite sheet is converted into a keypad, the keypad does not include a fragile configuration as in a conventional flexible keypad, and may thus achieve innovative flexibility, portability and durability that may satisfy the function as a keypad even after the rough wrinkle or folding required in daily life.

Also, since the keypad may be manufactured only with the conductive particles dispersed in the composite sheet without a specific pattern, it is unnecessary to use a high-cost manufacturing process conventionally used for forming a pattern, so that manufacturing costs of the keypad itself may be greatly reduced.

Also, since information on the pressure intensity as well as the position of the pressure applied to the composite sheet is obtained, separate recognition of the pressure intensity makes it possible to input more various types of information in the same area as compared with conventional keypads.

The effects of the invention are not limited to the effects mentioned above, and other advantages not mentioned in this specification will be apparent to those skilled in the art from the following description.

What is claimed is:

1. A method of converting a composite sheet into a multifunctional flexible keypad, the method comprising:
preparing a composite sheet including a flexible sheet and conductive particles dispersed therein;
detecting and collecting position information on an applied pressure and a change in electrical resistance of the composite sheet from a plurality of probe terminals provided on the sheet while applying a pressure a plurality of times to an arbitrary position of the composite sheet;
performing machine learning using the collected position information and electrical resistance information; and
estimating position information on a pressure applied by a user to the composite sheet by using a Deep Neural Network (DNN) model derived through the machine learning when the user applies the pressure to a predetermined position of the composite sheet.

2. The method of claim 1,
wherein the flexible sheet converts a composite sheet made of a polymer material into a multifunction flexible keypad.

3. The method of claim 1,
wherein the flexible sheet is one selected from polydimethylsiloxane (PDMS), polymethylmethacrylate (PMMA), epoxy resin, urethane resin or Ecoflex.

4. The method of claim 1,
wherein the conductive particles comprise at least one shape among a particulate shape, a fiber shape, a flake shape, and a plate shape.

5. The method of claim 1,
wherein the conductive particles are carbon nanotube (CNT).

6. The method of claim 1,
wherein said collecting the position information and the electrical resistance signal comprises:
dividing the composite sheet into predetermined virtual areas; and
detecting a pressure-applied virtual area and an electrical resistance signal generated in the composite sheet through a plurality of ports disposed at edges of the composite sheet.

7. The method of claim 1,
wherein pressure intensity information is additionally collected in addition to the position information of the applied pressure to perform machine learning, and
when a user applies a pressure to a predetermined position of the composite sheet, a Deep Neural Network (DNN) model created through the machine learning is used to derive position information and intensity information on the pressure applied by the user.

8. The method of claim 7,
wherein the intensity information is classified into three steps on the basis of the magnitude of intensity, and the meaning of the pressure applied in each step is recognized differently.

9. A flexible keypad comprising:
a flexible sheet in which conductive particles are dispersed; and
a plurality of probe terminals configured to detect a change in electrical resistance caused by a pressure applied to the flexible sheet from a plurality of positions of the flexible sheet.

10. The flexible keypad of claim 9,
wherein at least one among letters, numbers and symbols of the keypad is printed on one side of the flexible sheet.
